(19) United States
(12) Patent Application Publication
(10) Pub. No.: US 2025/0183212 A1
(43) Pub. Date: Jun. 5, 2025

(54) SEMICONDUCTOR PACKAGE AND METHOD FOR MANUFACTURING THE SAME

(71) Applicant: SAMSUNG ELECTRONICS CO., LTD., SUWON-SI (KR)

(72) Inventors: CHEOL KIM, Suwon-si (KR); JAE JUN LEE, Suwon-si (KR); HUI YEONG JANG, Suwon-si (KR)

(21) Appl. No.: 18/882,186

(22) Filed: Sep. 11, 2024

(30) Foreign Application Priority Data
Dec. 5, 2023 (KR) 10-2023-0174087

(51) Int. Cl. H01L 23/00; H01L 23/31

(52) U.S. Cl. CPC H01L 24/16; H01L 24/13; H01L 24/81; H01L 23/3171; H01L 2224/13017; H01L 2224/13022; H01L 2224/13075; H01L 2224/16227; H01L 2224/16503; H01L 2224/81193; H01L 2224/81203

(57) ABSTRACT

A semiconductor package including a lower structure, a lower conductive pad disposed on an upper surface of the lower structure, a lower connection pad disposed on and connected to an upper surface of the lower conductive pad, an upper connection pad disposed on and spaced apart from an upper surface of the lower connection pad, an upper conductive pad disposed on and connected to an upper surface of the upper connection pad, an upper structure disposed on an upper surface of the upper conductive pad, and an intermetallic compound layer disposed between and in contact with at least a portion of the upper surface of the lower connection pad and a lower surface of the upper connection pad, where the intermetallic compound layer includes an intermetallic compound including the first metal, the second metal, and a third metal different from each of the first metal and the second metal.

### CROSS-REFERENCE TO RELATED APPLICATION

This U.S. nonprovisional application claims priority under 35 U.S.C. § 119 to Korean Patent Application No. 10-2023-0174087 filed on Dec. 5, 2023 in the Korean Intellectual Property Office, the disclosure of which is incorporated by reference herein in its entirety.

### TECHNICAL FIELD

The present disclosure relates to a semiconductor package and a method for manufacturing the semiconductor package and more particularly, a semiconductor package including an intermetallic compound layer between a lower connection pad and an upper connection pad.

### DISCUSSION OF RELATED ART

As the demand for high-performance and high-reliability electronic products rapidly increases, the need for securing the reliability of bonding between connection pads in a semiconductor package manufacturing process increases. For example, before a bonding process is performed, a chemical mechanical polishing (CMP) process may be performed to expose the connection pad to which a solder is to be attached. A surface of the connection pad may be etched into a concave shape by the chemical mechanical polishing (CMP) process. As a result, while performing the bonding process, defects may occur at a bonding interface between the connection pads or a gap may be formed between the connection pads, thereby reducing the reliability of the connection pad.

### SUMMARY

A semiconductor package including a lower structure and a lower conductive pad disposed on an upper surface of the lower structure. The semiconductor package further includes a lower connection pad disposed on and connected to an upper surface of the lower conductive pad and an upper connection pad disposed on and spaced apart from an upper surface of the lower connection pad. In one aspect, the lower connection pad includes a first metal and the upper connection pad includes a second metal. The semiconductor package further includes an upper conductive pad disposed on and connected to an upper surface of the upper connection pad and an upper structure disposed on an upper surface of the upper conductive pad. The semiconductor package further includes an intermetallic compound layer disposed between and in contact with at least a portion of the upper surface of the lower connection pad and a lower surface of the upper connection pad. In one aspect, the intermetallic compound layer includes an intermetallic compound including the first metal, the second metal, and a third metal different from each of the first metal and the second metal. In one aspect, a width of the lower connection pad measured in a horizontal direction is greater than a width of the upper connection pad measured in the horizontal direction.

A semiconductor package including a lower structure and a lower connection pad disposed on an upper surface of the lower structure, wherein the lower connection pad includes a first metal. The semiconductor package further includes an upper connection pad disposed on and spaced apart from an upper surface of the lower connection pad, wherein the upper connection pad includes the first metal and an upper structure disposed on an upper surface of the upper connection pad. The semiconductor package further includes an intermetallic compound layer disposed on and in contact with the upper surface of the lower connection pad and a lower surface of the upper connection pad. In one aspect, the intermetallic compound layer includes an intermetallic compound including the first metal and a second metal different from the first metal. The semiconductor package further includes an interlayer insulating layer disposed between the upper surface of the lower structure and a lower surface of the upper structure. In one aspect, the interlayer insulating layer is in contact with a sidewall of the lower connection pad, a sidewall of the upper connection pad, and at least a portion of a sidewall of the intermetallic compound layer. In one aspect, a width of the lower connection pad measured in a horizontal direction is greater than a width of the upper connection pad measured in the horizontal direction.

A method for manufacturing a semiconductor package including forming a lower connection pad on an upper surface of a lower structure, forming an upper connection pad on a lower surface of an upper structure, and forming a solder on a lower surface of the upper connection pad or an upper surface of the lower connection pad. In one aspect, the lower connection pad includes a first metal, the upper connection pad includes the first metal, and the solder includes a second metal different from the first metal. The method further includes positioning the lower surface of the upper connection pad on the upper surface of the lower connection pad and performing a thermal compression process such that a portion of the lower connection pad, the solder, and a portion of the upper connection pad are chemically bonded to form an intermetallic compound layer. In one aspect, the intermetallic compound layer includes an intermetallic compound including the first metal and the second metal. In one aspect, a width of the lower connection pad measured in the horizontal direction is greater than a width of the upper connection pad measured in the horizontal direction.

### BRIEF DESCRIPTION OF DRAWINGS

FIG. 1 is an example diagram of a semiconductor package according to some embodiments of the present disclosure.

FIG. 2 is an enlarged view of a region R1 depicted in FIG. 1.

FIG. 3 is an example diagram of an intermediate structure corresponding to an intermediate step of a method for manufacturing a semiconductor package according to some embodiments of the present disclosure.

FIG. 4 is an example diagram of a semiconductor package according to some embodiments of the present disclosure.

FIG. 5 is an enlarged view of a region R2 depicted in FIG. 4.

FIG. 6 is an example diagram of a semiconductor package according to some embodiments of the present disclosure.

FIG. 7 is an enlarged view of a region R3 depicted in FIG. 6.

FIG. 8 is an example diagram of a semiconductor package according to some embodiments of the present disclosure.

FIG. 9 is an enlarged view of a region R4 depicted in FIG. 8.

FIG. 10 is an example diagram of an intermediate structure corresponding to an intermediate step of a method for manufacturing a semiconductor package according to some embodiments of the present disclosure.

FIG. 11 is an example diagram of a semiconductor package according to some embodiments of the present disclosure.

FIG. 12 is an enlarged view of a region R5 depicted in FIG. 11.

FIG. 13 is an example diagram of an intermediate structure corresponding to an intermediate step of a method for manufacturing a semiconductor package according to some embodiments of the present disclosure.

### DETAILED DESCRIPTIONS

Hereinafter, the inventive concepts are described in more detail. For simplicity and clarity of illustration, elements in the drawings are not necessarily drawn to scale. In some cases, for example, a shape, a size, a ratio, an angle, or a number, disclosed in the drawings for illustrating embodiments of the present disclosure are illustrative, and the present disclosure is not necessarily limited thereto. The same reference numbers in different drawings represent the same or similar elements, and as such perform similar functionality.

Further, descriptions and details of well-known steps and elements may be omitted for simplicity of the description. Furthermore, in the following detailed description of the present disclosure, numerous specific details are described to provide a thorough understanding of the present disclosure. However, it will be understood that the present disclosure may be practiced without these specific details. In some cases, well-known methods, procedures, components, and circuits have not been described in detail so as not to unnecessarily obscure aspects of the present disclosure. Examples of various embodiments are illustrated and described further below. It will be understood that the description herein is not intended to limit the claims to the specific embodiments described. On the contrary, it is intended to cover alternatives, modifications, and equivalents as may be included in the spirit and scope of the present disclosure as defined by the claims.

The terminology used herein is to describe particular embodiments and is not intended to limit the present disclosure. For example, the singular forms “a” and “an” are intended to include the plural forms as well (e.g., one or more), unless the context explicitly indicates otherwise. It will be further understood that the terms “comprises”, “comprising”, “includes”, and “including” when used in this specification, specify the presence of the stated features, integers, operations, elements, and/or components, but do not preclude the presence or addition of one or more other features, integers, operations, elements, components, and/or portions thereof. For example, the term “and/or” includes any and all combinations of one or more of the associated listed items. Expressions such as “at least one of” when preceding a list of elements may modify the entirety of the list of elements and might not modify the individual elements of the list. When referring to “C to D”, this may represent C inclusive to D inclusive unless otherwise specified.

It will be understood that, although the terms “first”, “second”, “third”, and so on may be used herein to describe various elements, components, regions, layers, and/or sections, these elements, components, regions, layers, and/or sections should not be limited by these terms. These terms are used to distinguish one element, component, region, layer, or section from another element, component, region, layer, or section. Thus, a first element, component, region, layer, or section described below could be termed a second element, component, region, layer, or section, without departing from the spirit and scope of the present disclosure.

In addition, it will also be understood that when a first element or layer is referred to as being present “on”, “beneath”, or “below” a second element or layer, the first element may be disposed directly on or beneath the second element or may be disposed indirectly (e.g., spaced apart) on or beneath the second element with a third element or layer being disposed between the first and second elements or layers. It will be understood that when an element or layer is referred to as being “connected to”, or “coupled to” another element or layer, it may be directly on, connected to, or coupled to the other element or layer, or one or more intervening elements or layers may be present. In some cases, when an element is “connected to” another element, the two elements may be electrically or physically connected. In addition, it will also be understood that when an element or layer is referred to as being “between” two elements or layers, it may be the only element or layer between the two elements or layers, or one or more intervening elements or layers may also be present.

Further, when a layer, film, region, plate, or the like is disposed “on” or “on a top” of another layer, film, region, plate, or the like, the former may directly contact the latter or another layer, film, region, plate, or the like may be disposed between the former and the latter. For example, when a layer, film, region, plate, or the like is directly disposed “on” or “on a top” of another layer, film, region, plate, or the like, the former directly contacts the latter and another layer, film, region, plate, or the like is not disposed between the former and the latter. Furthermore, for example, when a layer, film, region, plate, or the like is disposed “below” or “under” another layer, film, region, plate, or the like, the former may directly contact the latter or another layer, film, region, plate, or the like may be disposed between the former and the latter. In some cases, when a layer, film, region, plate, or the like is directly disposed “below” or “under” another layer, film, region, plate, or the like, the former directly contacts the latter, and another layer, film, region, plate, or the like is not disposed between the former and the latter.

Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning consistent with the meaning in the context of the relevant art and will not be interpreted in an idealized or overly formal sense unless expressly so defined herein.

In some cases, for example, when a certain embodiment may be implemented differently, a function or operation specified in a specific block may occur in a sequence different from that specified in a flowchart. For example, two consecutive blocks may be executed at the same time. Depending on a related function or operation, the blocks may be executed in a reverse sequence.

In descriptions of temporal relationships, for example, temporal precedent relationships between two events such as “after”, “subsequent to”, or “before”, another event may occur between the two events unless “directly after”, “directly subsequent” or “directly before” is indicated.

The features of the various embodiments of the present disclosure may be partially or entirely combined with each other, and may be technically associated with each other or operate with each other. The embodiments may be implemented independently of each other and may be implemented together in an association relationship.

Spatially relative terms, such as “beneath,” “below,” “lower,” “under,” “above,” “upper,” and the like, may be used for ease of explanation to describe the relationship of an element or feature to another element or feature as illustrated in the figures. It will be understood that the spatially relative terms are intended to encompass different orientations of the device in use or in operation, in addition to the orientation depicted in the figures. For example, when the device in the drawings is turned upside down, elements described as “below” or “beneath” or “under” other elements or features would then be oriented “above” the other elements or features. Thus, the example terms “below” and “under” may encompass both an orientation of above and below. The device may be otherwise oriented, for example, rotated 90 degrees or at other orientations, and the spatially relative descriptors used herein should be interpreted accordingly.

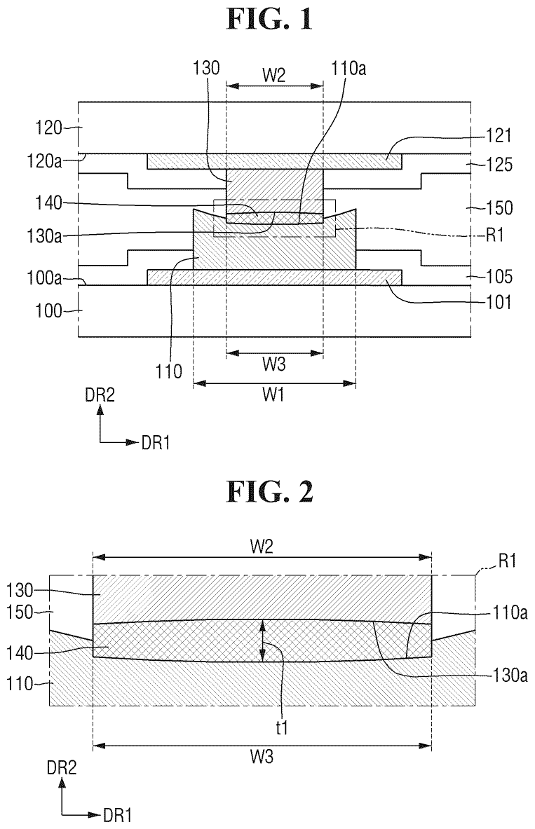

Hereinafter, a semiconductor package according to some embodiments of the present disclosure is described with reference to FIG. 1 and FIG. 2. FIG. 1 is an example diagram of a semiconductor package according to some embodiments of the present disclosure. FIG. 2 is an enlarged view of a region R1 depicted in FIG. 1.

Referring to FIG. 1 and FIG. 2, the semiconductor package includes a lower structure 100, a lower conductive pad 101, a lower passivation layer 105, a lower connection pad 110, an upper structure 120, an upper conductive pad 121, an upper passivation layer 125, an upper connection pad 130, an intermetallic compound layer 140, and an interlayer insulating layer 150.

In some embodiments, for example, the lower structure 100 may include a printed circuit board (PCB) or a ceramic substrate. However, the present disclosure is not necessarily limited thereto. In some embodiments, the lower structure 100 may be a redistribution layer including a plurality of wirings therein. In some embodiments, the lower structure 100 may be an interposer.

According to some embodiments, the lower structure 100 includes a printed circuit board, where the lower structure 100 may include phenol resin, epoxy resin, polyimide, or a combination thereof. For example, the lower structure 100 may include FR4, tetrafunctional epoxy, polyphenylene ether, epoxy/polyphenylene oxide, BT (bismaleimide triazine), thermount, cyanate ester, polyimide, liquid crystal polymer, or a combination thereof.

Hereinafter, a horizontal direction DR1 may be a direction parallel to an upper surface 100a of the lower structure 100. A vertical direction DR2 may be a direction perpendicular to the horizontal direction DR1. For example, the vertical direction DR2 may be a direction perpendicular to the upper surface 100a of the lower structure 100. In some cases, the vertical direction DR2 may be parallel to a side surface of the lower structure 100.

In some embodiments, the lower conductive pad 101 may be disposed on the upper surface 100a of the lower structure 100. The lower conductive pad 101 may be in contact with the upper surface 100a of the lower structure 100. In FIG. 1, the lower conductive pad 101 is shown as protruding from the upper surface 100a of the lower structure 100 along the vertical direction DR2. However, the present disclosure is not necessarily limited thereto. In some embodiments, the lower conductive pad 101 may be embedded within the lower structure 100. For example, an upper surface of the lower conductive pad 101 may be in a same level as the upper surface 100a of the lower structure 100.

The lower conductive pad 101 may include a conductive material. For example, the lower conductive pad 101 may include copper (Cu), silver (Ag), nickel (Ni), cobalt (Co), tantalum (Ta), indium (In), tin (Sn), zinc (Zn), manganese (Mn), titanium (Ti), magnesium (Mg), chromium (Cr), germanium (Ge), strontium (Sr), platinum (Pt), aluminum (Al), zirconium (Zr), or a combination thereof. However, the present disclosure is not necessarily limited thereto.

In some embodiments, the lower passivation layer 105 may be disposed on the upper surface 100a of the lower structure 100 and an upper surface and a sidewall of the lower conductive pad 101. The lower passivation layer 105 may be in contact with each of the upper surface 100a of the lower structure 100 and the upper surface and the sidewall of the lower conductive pad 101. For example, the lower passivation layer 105 may be formed conformally. However, the present disclosure is not necessarily limited thereto. The lower passivation layer 105 may include an insulating material. For example, the lower passivation layer 105 may include silicon oxide, silicon nitride, silicon oxynitride, or a combination thereof. However, the present disclosure is not necessarily limited thereto.

In some embodiments, the lower connection pad 110 may be disposed on the upper surface of the lower conductive pad 101. The lower connection pad 110 may extend through the lower passivation layer 105 along the vertical direction DR2 and may be connected to the lower conductive pad 101. For example, a portion of the sidewall of the lower connection pad 110 may be in contact with the lower passivation layer 105. A lower surface of the lower connection pad 110 may be in contact with the upper surface of the lower conductive pad 101.

In some cases, for example, a width W1 of the lower connection pad 110 measured in the horizontal direction DR1 may be smaller than a width of the lower conductive pad 101 measured in the horizontal direction DR1. For example, the width W1 of the lower connection pad 110 measured in the horizontal direction DR1 may range from 0.5 μm to 15 μm. For example, the upper surface 110a of the lower connection pad 110 may be formed concavely toward the upper surface 100a of the lower structure 100.

The lower connection pad 110 may include a first metal. For example, the first metal included in the lower connection pad 110 may include one of copper (Cu), nickel (Ni), and cobalt (Co). In some embodiments, the first metal included in the lower connection pad 110 may include silver (Ag), tantalum (Ta), indium (In), tin (Sn), zinc (Zn), manganese (Mn), titanium (Ti), magnesium (Mg), chromium (Cr), germanium (Ge), strontium (Sr), platinum (Pt), aluminum (Al), zirconium (Zr), or a combination thereof.

The upper structure 120 may be disposed on an upper surface of the lower passivation layer 105 and an upper surface 110a of the lower connection pad 110. The upper structure 120 may be spaced apart from each of the upper surface of the lower passivation layer 105 and the upper surface 110a of the lower connection pad 110 along the vertical direction DR2. The upper structure 120 may be, for example, a printed circuit board (PCB) or a ceramic substrate. However, the present disclosure is not necessarily limited thereto. In some embodiments, the upper structure 120 may be a redistribution layer including a plurality of wirings therein. In some embodiments, the upper structure 120 may be an interposer. In some embodiments, the upper structure 120 may be a semiconductor package.

In some embodiments, the upper structure 120 may be a semiconductor chip. For example, the upper structure 120 may be a logic semiconductor chip. For example, the upper structure 120 may be a CPU (Central Processing Unit), a GPU (Graphic Processing Unit), a FPGA (Field-Programmable Gate Array), an application processor (AP) such as a digital signal processor, a cryptographic processor, a microprocessor, a microcontroller, and/or an ASIC (Application-Specific IC). However, the present disclosure is not necessarily limited thereto.

For example, the upper structure 120 may be a memory semiconductor chip. For example, the upper structure 120 may be a volatile memory semiconductor chip such as DRAM (Dynamic Random Access Memory) or SRAM (Static Random Access Memory). For example, the upper structure 120 may be a non-volatile memory semiconductor chip such as flash memory, PRAM (Phase-change Random Access Memory), MRAM (Magnetoresistive Random Access Memory), FeRAM (Ferroelectric Random Access Memory) or RRAM (ResistiveRandom Access Memory).

The upper conductive pad 121 may be disposed on a lower surface 120a of the upper structure 120. The upper conductive pad 121 may be in contact with the lower surface 120a of the upper structure 120. In FIG. 1, the upper conductive pad 121 may protrude from the lower surface 120a of the upper structure 120 along the vertical direction DR2. However, the present disclosure is not necessarily limited thereto. In some embodiments, the upper conductive pad 121 may be embedded within the upper structure 120. For example, a lower surface of the upper conductive pad 121 may be at a same level as the lower surface 120a of the upper structure 120.

The upper conductive pad 121 may include a conductive material. For example, the upper conductive pad 121 may include copper (Cu), silver (Ag), nickel (Ni), cobalt (Co), tantalum (Ta), indium (In), tin (Sn), zinc (Zn), manganese (Mn), titanium (Ti), magnesium (Mg), chromium (Cr), germanium (Ge), strontium (Sr), platinum (Pt), aluminum (Al), zirconium (Zr), or a combination thereof. However, the present disclosure is not necessarily limited thereto.

The upper passivation layer 125 may be disposed on the lower surface 120a of the upper structure 120 and a lower surface and a sidewall of the upper conductive pad 121. The upper passivation layer 125 may be in contact with each of the lower surface 120a of the upper structure 120 and the lower surface and the sidewall of the upper conductive pad 121. For example, the upper passivation layer 125 may be formed conformally. However, the present disclosure is not necessarily limited thereto. The upper passivation layer 125 may include an insulating material. For example, the upper passivation layer 125 may include silicon oxide, silicon nitride, silicon oxynitride, or a combination thereof. However, the present disclosure is not necessarily limited thereto.

The upper connection pad 130 may be disposed on the lower surface of the upper conductive pad 121. The upper connection pad 130 may extend through the upper passivation layer 125 along the vertical direction DR2 and may be connected to the upper conductive pad 121. For example, a portion of the sidewall of the upper connection pad 130 may be in contact with the upper passivation layer 125. The upper surface of the upper connection pad 130 may be in contact with a portion of the lower surface of the upper conductive pad 121.

The upper connection pad 130 may be disposed on the upper surface 110a of the lower connection pad 110. For example, a lower surface 130a of the upper connection pad 130 may face the upper surface 110a of the lower connection pad 110. For example, the upper connection pad 130 may be spaced apart from the lower connection pad 110 along the vertical direction DR2. However, the present disclosure is not necessarily limited thereto. In some embodiments, at least a portion of the lower surface 130a of the upper connection pad 130 may contact the upper surface 110a of the lower connection pad 110.

For example, a width W2 of the upper connection pad 130 measured in the horizontal direction DR1 may be smaller than a width of the upper conductive pad 121 measured in the horizontal direction DR1. For example, the width W2 of the upper connection pad 130 measured in the horizontal direction DR1 may be smaller than the width W1 of the lower connection pad 110 measured in the horizontal direction DR1. For example, the width W2 of the upper connection pad 130 measured in the horizontal direction DR1 may range from 0.25 μm to 10 μm. For example, the lower surface 130a of the upper connection pad 130 may be formed concavely toward the lower surface 120a of the upper structure 120.

The upper connection pad 130 may include a second metal. For example, the second metal included in the upper connection pad 130 may include one of copper (Cu), nickel (Ni), and cobalt (Co). In some embodiments, the second metal included in the upper connection pad 130 may include silver (Ag), tantalum (Ta), indium (In), tin (Sn), zinc (Zn), manganese (Mn), titanium (Ti), magnesium (Mg), chromium (Cr), germanium (Ge), strontium (Sr), platinum (Pt), aluminum (Al), zirconium (Zr), or a combination thereof.

In some cases, for example, the second metal included in the upper connection pad 130 may be the same as the first metal included in the lower connection pad 110. However, the present disclosure is not necessarily limited thereto. In some embodiments, the second metal included in the upper connection pad 130 may be different from the first metal included in the lower connection pad 110.

The intermetallic compound layer 140 may be disposed between the upper surface 110a of the lower connection pad 110 and the lower surface 130a of the upper connection pad 130. For example, the intermetallic compound layer 140 may contact each of the upper surface 110a of the lower connection pad 110 and the lower surface 130a of the upper connection pad 130. For example, at least a portion of the intermetallic compound layer 140 may be disposed inside the lower connection pad 110. For example, at least a portion of a sidewall of the intermetallic compound layer 140 may be in contact with the lower connection pad 110. In some cases, for example, at least a portion of a sidewall of the intermetallic compound layer 140 may be in contact with a portion of the side surface of the lower connection pad 110.

For example, a width W3 of the intermetallic compound layer 140 measured in the horizontal direction DR1 may be equal to the width W2 of the upper connection pad 130 measured in the horizontal direction DR1. For example, the width W3 of the intermetallic compound layer 140 measured in the horizontal direction DR1 may range from 0.25 μm to 10 μm. For example, a thickness t1 of the intermetallic compound layer 140 measured in the vertical direction DR2 may be smaller than a thickness of the lower connection pad 110 measured in the vertical direction DR2. In some cases, the thickness t1 of the intermetallic compound layer 140 measured in the vertical direction DR2 may be smaller than a thickness of the upper connection pad 130 measured in the vertical direction DR2. For example, the thickness t1 of the intermetallic compound layer 140 measured in the vertical direction DR2 may range from 0.0005 μm to 0.01 μm. In some cases, the thickness t1 of the intermetallic compound layer 140 measured in the vertical direction DR2 may be the largest at a center point of the intermetallic compound layer 140 and may be the smallest at an end or side surface of the intermetallic compound layer 140.

The intermetallic compound layer 140 may include an intermetallic compound. In some cases, for example, the intermetallic compound layer 140 may uniformly include the intermetallic compound. In some cases, for example, the intermetallic compound layer 140 may partially include the intermetallic compound. For example, the intermetallic compound layer 140 may include the intermetallic compound, the first metal, the second metal, the third metal, or a combination thereof. For example, the intermetallic compound layer 140 may be formed as a single layer including a single intermetallic compound. However, the present disclosure is not necessarily limited thereto.

The intermetallic compound layer 140 may include the first metal included in the lower connection pad 110, the second metal included in the upper connection pad 130, and a third metal different from each of the first metal and the second metal. For example, the intermetallic compound layer 140 may include an intermetallic compound in which the third metal has a chemical bond to each of the first metal and the second metal. For example, the third metal may include tin (Sn). In some embodiments, the third metal may include one of indium (In), lead (Pb), zinc (Zn), nickel (Ni), gold (Au), silver (Ag), copper (Cu), antimony (Sb), or bismuth (Bi).

For example, each of the first metal and the second metal may include copper (Cu), and the third metal may include tin (Sn). Accordingly, the intermetallic compound included in the intermetallic compound layer 140 may be Cu₃Sn. For example, each of the first metal and the second metal may include nickel (Ni), and the third metal may include tin (Sn). Accordingly, the intermetallic compound included in the intermetallic compound layer 140 may be Ni₃Sn₄. For example, each of the first metal and the second metal may include cobalt (Co), and the third metal may include tin (Sn). Accordingly, the intermetallic compound included in the intermetallic compound layer 140 may be CoSn₂. The above-described intermetallic compound included in the intermetallic compound layer 140 is described as an example, and the present disclosure is not necessarily limited thereto.

The interlayer insulating layer 150 may be disposed between the upper surface 100a of the lower structure 100 and the lower surface 120a of the upper structure 120. For example, the interlayer insulating layer 150 may be disposed between the upper surface of the lower passivation layer 105 and the lower surface of the upper passivation layer 125. The interlayer insulating layer 150 may be in contact with each of the upper surface of the lower passivation layer 105 and the lower surface of the upper passivation layer 125.

The interlayer insulating layer 150 may surround each of a sidewall of the lower connection pad 110 and a sidewall of the upper connection pad 130. The interlayer insulating layer 150 may be in contact with each of the sidewall of the lower connection pad 110 and the sidewall of the upper connection pad 130. For example, the interlayer insulating layer 150 may contact the upper surface 110a of the lower connection pad 110 while being disposed on each of the sidewall of the upper connection pad 130 and the sidewall of the intermetallic compound layer 140. The interlayer insulating layer 150 may be in contact with a portion of the sidewall of the intermetallic compound layer 140. However, the present disclosure is not necessarily limited thereto. In some embodiments, the interlayer insulating layer 150 may be spaced apart from the sidewall of the intermetallic compound layer 140.

The interlayer insulating layer 150 may include an insulating material. For example, the interlayer insulating layer 150 may include silicon oxide, silicon nitride, silicon oxynitride, or a combination thereof. In some embodiments, the interlayer insulating layer 150 may include tetraethyl orthosilicate (TEOS).

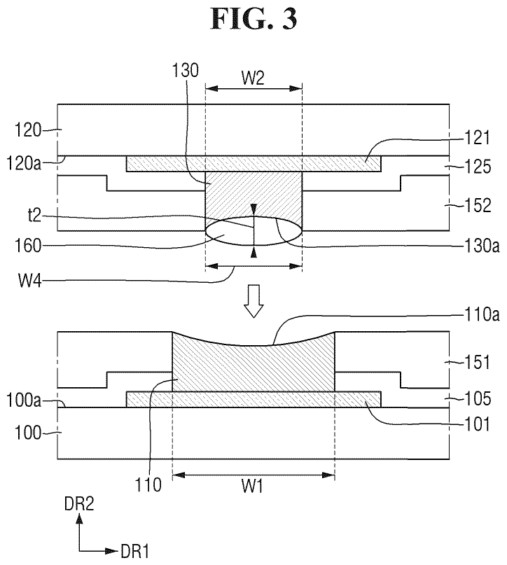

Hereinafter, a method for manufacturing a semiconductor package according to some embodiments of the present disclosure is described with reference to FIGS. 1 to 3. FIG. 3 is an example diagram of an intermediate structure corresponding to an intermediate step of a method for manufacturing a semiconductor package according to some embodiments of the present disclosure.

Referring to FIG. 3, the lower conductive pad 101 may be formed on the upper surface 100a of the lower structure 100. Subsequently, the lower passivation layer 105 may be formed on the upper surface 100a of the lower structure 100 and the upper surface and the sidewall of the lower conductive pad 101. For example, the lower passivation layer 105 may be formed conformally. Subsequently, the lower interlayer insulating layer 151 may be formed on the upper surface of the lower passivation layer 105. For example, the lower interlayer insulating layer 151 may include silicon oxide, silicon nitride, silicon oxynitride, tetraethyl orthosilicate (TEOS), or a combination thereof. Subsequently, the lower connection pad 110 may be formed which extends through the lower interlayer insulating layer 151 and the lower passivation layer 105 along the vertical direction DR2 and may be connected to the lower conductive pad 101. For example, in the process of forming the lower connection pad 110, a chemical mechanical polishing (CMP) process may be performed. For example, after the CMP process is performed, the upper surface 110a of the lower connection pad 110 may be formed concavely toward the upper surface 100a of the lower structure 100.

The CMP process is used in the semiconductor manufacturing process for surface planarization. For example, the CMP process includes applying abrasive particles or chemical additives to a substrate (e.g., the lower passivation layer 105). Then, mechanical polishing is performed to remove material to create a surface. Then, the substrate may be rinsed to remove residues.

Furthermore, the upper conductive pad 121 may be formed on the lower surface 120a of the upper structure 120. Subsequently, the upper passivation layer 125 may be formed on the lower surface 120a of the upper structure 120 and the lower surface and the sidewall of the upper conductive pad 121. For example, the upper passivation layer 125 may be formed conformally. Subsequently, the upper interlayer insulating layer 152 may be formed on the lower surface of the upper passivation layer 125. For example, the upper interlayer insulating layer 152 may include silicon oxide, silicon nitride, silicon oxynitride, tetraethyl orthosilicate (TEOS), or a combination thereof. Subsequently, the upper connection pad 130 may be formed through the upper interlayer insulating layer 152 and the upper passivation layer 125 along the vertical direction DR2 and connected to the upper conductive pad 121. For example, in the process of forming the upper connection pad 130, a CMP process may be performed. For example, after the CMP process is performed, the lower surface 130a of the upper connection pad 130 may be formed concavely toward the lower surface 120a of the upper structure 120. For example, the width W2 of the upper connection pad 130 measured in the horizontal direction DR1 may be smaller than the width W1 of the lower connection pad 110 measured in the horizontal direction DR1.

Subsequently, a solder 160 may be formed on the lower surface 130a of the upper connection pad 130. The solder 160 may be attached to the lower surface 130a of the upper connection pad 130. For example, the solder 160 may protrude downwardly beyond the lower surface of the upper interlayer insulating layer 152. In some cases, a level of the lower surface of the solder 160 may be lower than a level of the lower surface of the upper interlayer insulating layer 152. For example, a width W4 of the solder 160 measured in the horizontal direction DR1 may be smaller than the width W1 of the lower connection pad 110 measured in the horizontal direction DR1. For example, the width W4 of the solder 160 measured in the horizontal direction DR1 may be equal to the width W2 of the upper connection pad 130 measured in the horizontal direction DR1. For example, the width W4 of the solder 160 measured in the horizontal direction DR1 may range from 0.25 μm to 10 μm.

For example, a thickness t2 of the solder 160 measured in the vertical direction DR2 may be smaller than the thickness of the lower connection pad 110 measured in the vertical direction DR2. Furthermore, the thickness t2 of the solder 160 measured in the vertical direction DR2 may be smaller than the thickness of the upper connection pad 130 measured in the vertical direction DR2. For example, the solder 160 may include the third metal. For example, the third metal may include tin (Sn). In some embodiments, the third metal may include one of indium (In), lead (Pb), zinc (Zn), nickel (Ni), gold (Au), silver (Ag), copper (Cu), antimony (Sb), or bismuth (Bi).

Subsequently, the lower surface 130a of the upper connection pad 130 may be disposed on the upper surface 110a of the lower connection pad 110. In some cases, the lower surface 130a of the upper connection pad 130 may be spaced apart from the upper surface 110a of the lower connection pad 110. For example, the solder 160 attached to the lower surface 130a of the upper connection pad 130 may be disposed on the upper surface 110a of the lower connection pad 110. Subsequently, the solder 160 may be attached to the upper surface 110a of the lower connection pad 110 by performing a thermal compression process thereon. In one aspect, the thermal compression process bonds the surfaces by applying heat and pressure. For example, a portion of the lower surface 130a of the upper connection pad 130 may be connected to a portion of the upper surface 110a of the lower connection pad 110 through solder 160.

Referring to FIG. 1 and FIG. 2, while the thermal compression process is performed, the solder (e.g., the solder 160 described with reference to FIG. 3) may be chemically bonded to each of a portion of the lower connection pad 110 and a portion of the upper connection pad 130. Thus, the intermetallic compound layer 140 may be formed between the upper surface 110a of the lower connection pad 110 and the lower surface 130a of the upper connection pad 130. For example, the intermetallic compound layer 140 may be formed as a layer by chemically bonding the portion of the lower connection pad 110, the solder (e.g., the solder 160 described with reference to FIG. 3), and the portion of the upper connection pad 130. After the thermal compression process is performed, the lower interlayer insulating layer (e.g., the lower interlayer insulating layer 151 described with reference to FIG. 3) and the upper interlayer insulating layer (e.g., the upper interlayer insulating layer 152 described with reference to FIG. 3) may become the interlayer insulating layer 150.

For example, the intermetallic compound layer 140 may include an intermetallic compound produced by chemically bonding the third metal included in the solder 160 and the first metal included in the lower connection pad 110. In some cases, the intermetallic compound layer 140 may include an intermetallic compound produced by chemically bonding the third metal included in the solder 160 and the second metal included in the upper connection pad 130. In some cases, the intermetallic compound layer 140 may include an intermetallic compound produced by chemically bonding the third metal included in the solder 160, the first metal included in the lower connection pad 110, and the second metal included in the upper connection pad 130. The third metal may be different from each of the first and second metals. In some cases, for example, the first metal and the second metal may be the same. However, the present disclosure is not necessarily limited thereto. In some embodiments, the first metal and the second metal may be different from each other.

For example, the width W3 of the intermetallic compound layer 140 measured in the horizontal direction DR1 may be equal to the width W4 of the solder 160 (as shown in FIG. 3) measured in the horizontal direction DR1. For example, the thickness t1 of the intermetallic compound layer 140 measured in the vertical direction DR2 may be smaller than the thickness t2 of the solder 160 measured in the vertical direction DR2.

During the process of forming the intermetallic compound layer 140, the third metal has chemically bonded with each of the first metal and the second metal, and thus, a total volume of the solder 160 is reduced. In some cases, in the process of forming the intermetallic compound layer 140, each of the portion of the lower connection pad 110 and the portion of the upper connection pad 130 is converted into the intermetallic compound layer 140, a total volume may be reduced due to the chemical bonding between the first, second, and third metals. Thus, a volume of the intermetallic compound layer 140 may be smaller than a volume of the solder 160.

In the method for manufacturing the semiconductor package according to some embodiments of the present disclosure, the lower connection pad 110, the solder 160, and the upper connection pad 130 may be connected to each other via an intermetallic chemical bond, so that the reliability of bonding between the upper connection pad 130 and the lower connection pad 110 and may be improved. For example, the lower connection pad 110, the solder 160, and the upper connection pad 130 may be connected to each other via the intermetallic chemical bond, thereby preventing a defect from occurring at a bonding interface between the lower connection pad 110 and the upper connection pad 130. Furthermore, the lower connection pad 110, the solder 160, and the upper connection pad 130 may be connected to each other via the intermetallic chemical bond, so that a formation of a gap may be prevented between the lower connection pad 110 and the upper connection pad 130.

According to some embodiments of the present disclosure, the intermetallic compound layer 140 including the intermetallic compound may be disposed between the upper surface 110a of the lower connection pad 110 and the lower surface 130a of the upper connection pad 130. The volume of the intermetallic compound layer 140 may be smaller than the volume of the solder 160 used in the manufacturing process. As a result, a spacing between the lower connection pad 110 and the upper connection pad 130 may be reduced such that the reliability of a connection relationship between the lower connection pad 110 and the upper connection pad 130 may be improved.

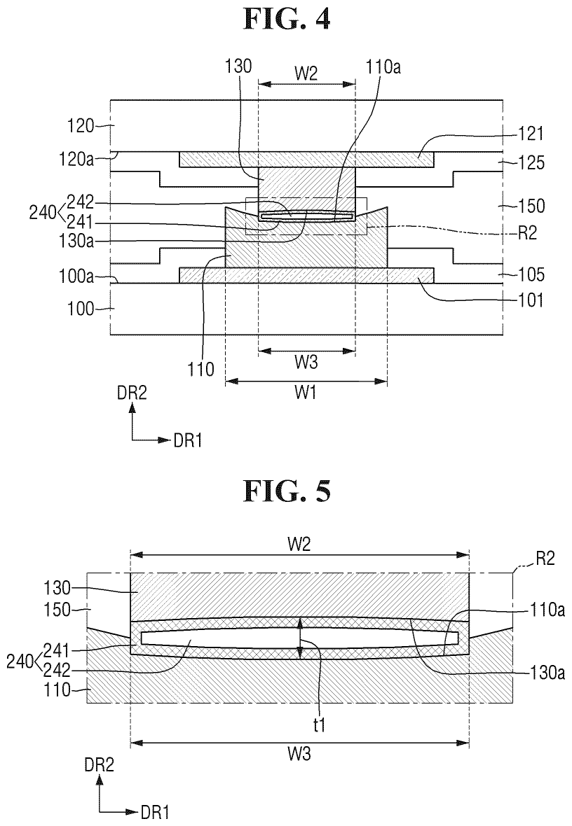

A semiconductor package according to some embodiments of the present disclosure is described with reference to FIG. 4 and FIG. 5. The differences between the semiconductor package depicted in FIGS. 4 and 5 and the semiconductor package depicted in FIGS. 1 and 2 are described. FIG. 4 is an example diagram of a semiconductor package according to some embodiments of the present disclosure. FIG. 5 is an enlarged view of a region R2 depicted in FIG. 4.

Referring to FIG. 4 and FIG. 5, the intermetallic compound layer 240 may be formed as a double film, whereas the intermetallic compound layer 140 depicted in FIGS. 1 and 2 may be formed as a single layer. For example, the intermetallic compound layer 240 may include a first layer 241 and a second layer 242. For example, the first layer 241 may be disposed on and in contact with each of the lower connection pad 110 and the upper connection pad 130. Furthermore, at least a portion of the first layer 241 may be in contact with the interlayer insulating layer 150. For example, a portion of a side surface of the first layer of the intermetallic compound layer 240 may be in contact with the interlayer insulating layer 150. For example, the first layer 241 may be a surface of the intermetallic compound layer 240. For example, the first layer 241 may include an intermetallic compound produced by chemically bonding the third metal to each of the first metal and the second metal.

The second layer 242 may be disposed in an inner region of the first layer 241. For example, the second layer 242 may be surrounded by the first layer 241. For example, the second layer 242 may be spaced apart from each of the lower connection pad 110, the upper connection pad 130, and the interlayer insulating layer 150. The second layer 242 may include a material different from that of the first layer 241. For example, the second layer 242 may include the same material as that of the solder 160 shown in FIG. 3. For example, the second layer 242 may include the third metal.

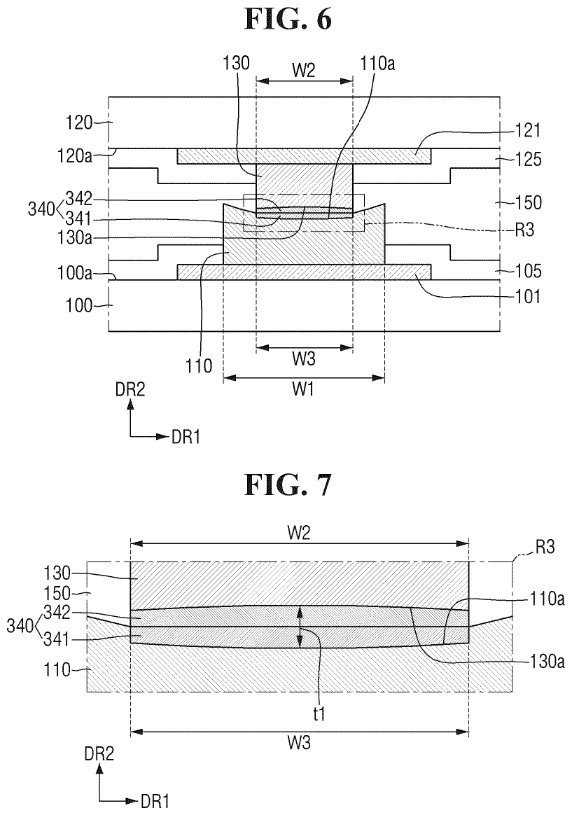

A semiconductor package according to some embodiments of the present disclosure is described with reference to FIG. 6 and FIG. 7. The differences between the semiconductor package depicted in FIGS. 6 and 7 and the semiconductor package depicted in FIGS. 1 and 2 are described. FIG. 6 is an example diagram of a semiconductor package according to some embodiments of the present disclosure. FIG. 7 is an enlarged view of a region R3 depicted in FIG. 6.

Referring to FIG. 6 and FIG. 7, the lower connection pad 110 and the upper connection pad 130 may include different metals, and the intermetallic compound layer 340 may be formed as a double film, in contrast, the intermetallic compound layer 140 depicted in FIGS. 1 and 2 may be formed as a single layer. For example, the first metal included in the lower connection pad 110 may be different from the second metal included in the upper connection pad 130. For example, the intermetallic compound layer 340 may include a first layer 341 and a second layer 342. The first layer 341 may be disposed on and in contact with the lower connection pad 110. For example, the first layer 341 may be in contact with the upper surface 110a of the lower connection pad 110. For example, the side surface of the first layer 341 of the intermetallic compound layer 340 may be in contact with the side surface of the lower connection pad 110. For example, the first layer 341 may include a first intermetallic compound in which the third metal has a chemical bond with the first metal.

For example, the second layer 342 may be disposed on and in contact with the upper surface of the first layer 341. The second layer 342 may be disposed on and in contact with the upper connection pad 130. For example, the second layer 342 may be in contact with the lower surface 130a of the upper connection pad 130. For example, a sidewall of the second layer 342 may contact the interlayer insulating layer 150. For example, the second layer 342 may include a second intermetallic compound in which the third metal has a chemical bond with a second metal. The second intermetallic compound may include a material different from the first intermetallic compound. For example, the second layer 342 may include a material different from that of the first layer 341.

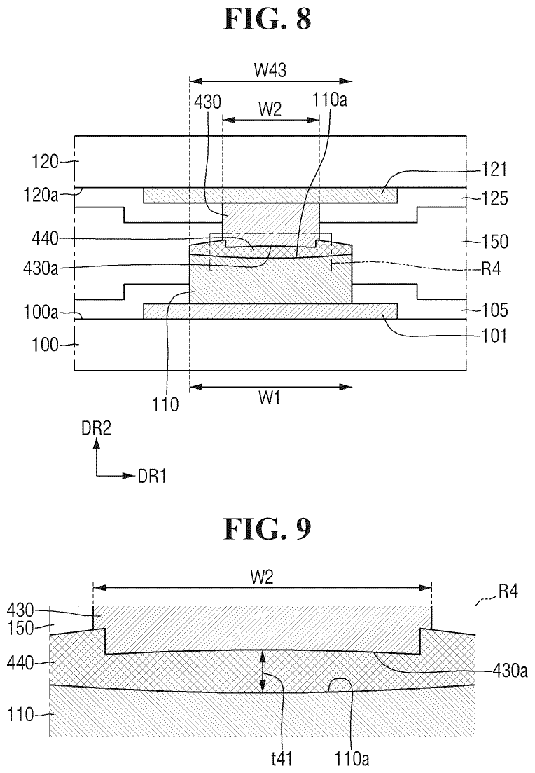

A semiconductor package according to some embodiments of the present disclosure is described with reference to FIG. 8 and FIG. 9. The differences between the semiconductor package depicted in FIGS. 8 and 9 and the semiconductor package depicted in FIGS. 1 and 2 are described. FIG. 8 is an example diagram of a semiconductor package according to some embodiments of the present disclosure. FIG. 9 is an enlarged view of a region R4 depicted in FIG. 8.

Referring to FIG. 8 and FIG. 9, at least a portion of an intermetallic compound layer 440 may be disposed on a sidewall of an upper connection pad 430. For example, at least a portion of the upper connection pad 430 may be disposed inside the intermetallic compound layer 440. For example, at least a portion of the upper connection pad 430 may be surrounded by the intermetallic compound layer 440. For example, at least a portion of the intermetallic compound layer 440 may contact a portion of a sidewall of the upper connection pad 430. For example, a portion of the intermetallic compound layer 440 may be disposed between the upper surface 110a of the lower connection pad 110 and a lower surface 430a of the upper connection pad 430. The remaining portion of the intermetallic compound layer 440 may be disposed between the upper surface 110a of the lower connection pad 110 and the interlayer insulating layer 150. In some cases, for example, a level of a portion of the upper surface of intermetallic compound layer 440 is higher than a level of the lower surface 430a of the upper connection pad 430.

In some cases, for example, a width W43 of the intermetallic compound layer 440 measured in the horizontal direction DR1 may be equal to the width W1 of the lower connection pad 110 measured in the horizontal direction DR1. For example, a width of the portion of the upper connection pad 430 measured in the horizontal direction DR1 surrounded by the intermetallic compound layer 440 may be smaller than the width W2 of the upper connection pad 430 measured in the horizontal direction DR1 surrounded by the interlayer insulating layer 150. For example, a thickness t41 measured in the vertical direction DR2 of a portion of the intermetallic compound layer 440 disposed between the upper surface 110a of the lower connection pad 110 and the lower surface 430a of the upper connection pad 430 may be smaller than a thickness measured in the vertical direction DR2 of the remaining portion of the intermetallic compound layer 440 disposed between the upper surface 110a of the lower connection pad 110 and the interlayer insulating layer 150.

A method for manufacturing a semiconductor package according to some embodiments of the present disclosure is described with reference to FIGS. 8 to 10. The differences between the method for manufacturing the semiconductor package depicted in FIGS. 8 to 10 and the method for manufacturing the semiconductor package depicted in FIGS. 1 to 3 are described.

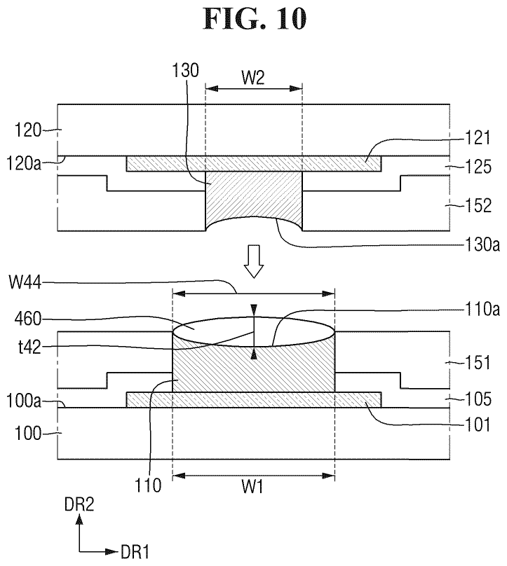

Referring to FIG. 10, a solder 460 may be formed on the upper surface 110a of the lower connection pad 110. The solder 460 may be disposed on and connected to the upper surface 110a of the lower connection pad 110. For example, the solder 460 may protrude upward away from the upper surface of the lower interlayer insulating layer 151. For example, a level of an upper surface of solder 460 may be higher than a level of an upper surface of the lower interlayer insulating layer 151. For example, a width W44 of the solder 460 measured in the horizontal direction DR1 may be larger than the width W2 of the upper connection pad 130 measured in the horizontal direction DR1. For example, the width W44 of the solder 460 measured in the horizontal direction DR1 may be equal to the width W1 of the lower connection pad 110 measured in the horizontal direction DR1. For example, the width W44 of the solder 460 measured in the horizontal direction DR1 may range from 0.5 μm to 15 μm.

For example, a thickness t42 of the solder 460 measured in the vertical direction DR2 may be smaller than the thickness of the lower connection pad 110 measured in the vertical direction DR2. Furthermore, the thickness t42 of the solder 460 measured in the vertical direction DR2 may be smaller than the thickness of the upper connection pad 130 measured in the vertical direction DR2. For example, the solder 460 may include the third metal. For example, the third metal may include tin (Sn). In some embodiments, the third metal may include one of indium (In), lead (Pb), zinc (Zn), nickel (Ni), gold (Au), silver (Ag), copper (Cu), antimony (Sb), or bismuth (Bi).

Subsequently, the lower surface 130a of the upper connection pad 130 may be disposed on the upper surface 110a of the lower connection pad 110. For example, the lower surface 130a of the upper connection pad 130 may be disposed on and in contact with the solder 460 connected to the upper surface 110a of the lower connection pad 110. Subsequently, the solder 460 may be connected to the lower surface 130a of the upper connection pad 130 by performing a thermal compression process thereon.

Referring to FIGS. 8 to 10, while the thermal compression process is performed, the solder 460 may be chemically bonded to each of the portion of the lower connection pad 110 and a portion of the upper connection pad 430. Thus, the intermetallic compound layer 440 may be formed between the upper surface 110a of the lower connection pad 110 and the lower surface 430a of the upper connection pad 430. For example, the intermetallic compound layer 440 may be formed as a layer by chemically bonding the portion of the lower connection pad 110, the solder 460, and the portion of the upper connection pad 430. After the thermal compression process is performed, the lower interlayer insulating layer 151 and the upper interlayer insulating layer 152 may become the interlayer insulating layer 150.

For example, the width W43 of the intermetallic compound layer 440 measured in the horizontal direction DR1 may be equal to the width W44 of the solder 460 measured in the horizontal direction DR1. For example, the thickness t41 of the intermetallic compound layer 440 measured in the vertical direction DR2 may be smaller than the thickness t42 of the solder 460 measured in the vertical direction DR2.

During the process of forming the intermetallic compound layer 440, the third metal is chemically bonded with each of the first metal and the second metal, such that a total volume of the solder 460 is reduced. In some cases, in the process of forming the intermetallic compound layer 440, each of the portion of the lower connection pad 110 and the portion of the upper connection pad 430 is converted into the intermetallic compound layer 440, a total volume may be reduced due to the chemical bonding between the first, second, and third metals. Thus, the volume of the intermetallic compound layer 440 may be smaller than the volume of the solder 460.

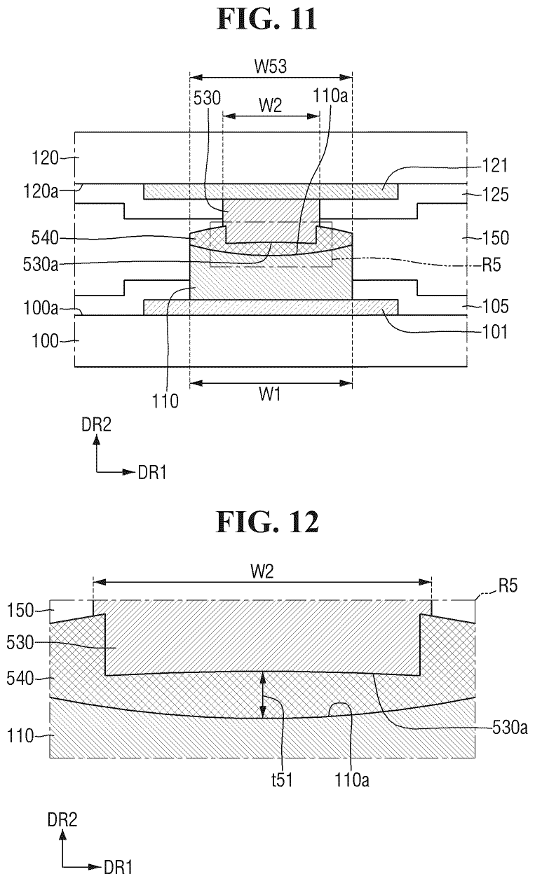

A semiconductor package according to some embodiments of the present disclosure is described with reference to FIG. 11 and FIG. 12. The differences between the semiconductor package depicted in FIGS. 11 and 12 and the semiconductor package depicted in FIGS. 1 and 2 are described. FIG. 11 is an example diagram of a semiconductor package according to some embodiments of the present disclosure. FIG. 12 is an enlarged view of a region R5 in FIG. 11.

Referring to FIG. 11 and FIG. 12, at least a portion of an intermetallic compound layer 540 may be disposed on a sidewall of an upper connection pad 530. For example, at least a portion of the upper connection pad 530 may be disposed inside the intermetallic compound layer 540. For example, the at least the portion of the upper connection pad 530 may be surrounded by the intermetallic compound layer 540. For example, at least a portion of the intermetallic compound layer 540 may contact a portion of a sidewall of the upper connection pad 530. For example, a portion of the intermetallic compound layer 540 may be disposed between the upper surface 110a of the lower connection pad 110 and a lower surface 530a of the upper connection pad 530. The remaining portion of the intermetallic compound layer 540 may be disposed between the upper surface 110a of the lower connection pad 110 and the interlayer insulating layer 150.

For example, a width W53 of the intermetallic compound layer 540 measured in the horizontal direction DR1 may be equal to the width W1 of the lower connection pad 110 measured in the horizontal direction DR1. For example, a width measured in the horizontal direction DR1 of the portion of the upper connection pad 530 surrounded by the intermetallic compound layer 540 may be smaller than the width W2 measured in the horizontal direction DR1 of the remaining portion of the upper connection pad 530 surrounded by the interlayer insulating layer 150. For example, a thickness t51 measured in the vertical direction DR2 of the portion of the intermetallic compound layer 540 disposed between the upper surface 110a of the lower connection pad 110 and the lower surface 530a of the upper connection pad 530 may be smaller than a thickness measured in the vertical direction DR2 of the remaining portion of the intermetallic compound layer 540 disposed between the upper surface 110a of the lower connection pad 110 and the interlayer insulating layer 150. For example, the thickness measured in the vertical direction DR2 of the remaining portion of the intermetallic compound layer 540 disposed between the upper surface 110a of the lower connection pad 110 and the interlayer insulating layer 150 may be larger than the thickness measured in the vertical direction DR2 of the remaining portion of the intermetallic compound layer (e.g., the intermetallic compound layer 440 described with reference to FIGS. 8 and 9) disposed between the upper surface 110a of the lower connection pad 110 and the interlayer insulating layer 150 in FIG. 8 and FIG. 9.

A method for manufacturing a semiconductor package according to some embodiments of the present disclosure is described with reference to FIGS. 11 to 13. The differences between the method for manufacturing the semiconductor package depicted in FIGS. 11 to 13 and the method for manufacturing the semiconductor package depicted in FIGS. 1 to 3 are described.

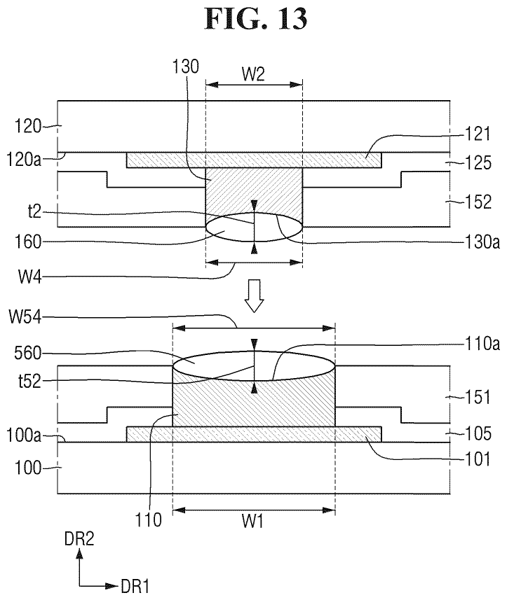

Referring to FIG. 13, a lower solder 560 may be formed on the upper surface 110a of the lower connection pad 110. The lower solder 560 may be connected to the upper surface 110a of the lower connection pad 110. For example, the lower solder 560 may protrude upward away from the upper surface of the lower interlayer insulating layer 151. For example, an upper surface of the lower solder 560 may be at a higher level than an upper surface of the lower interlayer insulating layer 151. For example, a width W54 of the lower solder 560 measured in the horizontal direction DR1 may be larger than the width W2 of the upper connection pad 130 measured in the horizontal direction DR1. For example, the width W54 of the lower solder 560 measured in the horizontal direction DR1 may be equal to the width W1 of the lower connection pad 110 measured in the horizontal direction DR1. For example, the width W54 of the lower solder 560 measured in the horizontal direction DR1 may range from 0.5 μm to 15 μm.

In some embodiments, an upper solder 160 may be formed on the lower surface 130a of the upper connection pad 130. The upper solder 160 may be connected to the upper surface 110a of the lower connection pad 110. For example, the upper solder 160 may protrude downward away from the lower surface of the upper interlayer insulating layer 152. For example, a lower surface of the upper solder may have a lower level than a lower surface of the upper interlayer insulating layer 152. For example, the width W4 of the upper solder 160 measured in the horizontal direction DR1 may be equal to the width W2 of the upper connection pad 130 measured in the horizontal direction DR1. For example, the width W4 of the upper solder 160 measured in the horizontal direction DR1 may range from 0.25 μm to 10 μm.

For example, a thickness t52 of the lower solder 560 measured in the vertical direction DR2 may be smaller than the thickness of the lower connection pad 110 measured in the vertical direction DR2. The thickness t2 of the upper solder 160 measured in the vertical direction DR2 may be smaller than the thickness of the upper connection pad 130 measured in the vertical direction DR2. In some cases, for example, the thickness t2 of the upper solder 160 is smaller than the thickness t52 of the lower solder 560. In some cases, for example, the thickness t2 of the upper solder 160 is the same as the thickness t52 of the lower solder 560. In some cases, for example, the thickness t2 of the upper solder 160 is larger than the thickness t52 of the lower solder 560. For example, each of the lower solder 560 and the upper solder 160 may include the third metal. For example, the third metal may include tin (Sn). In some embodiments, the third metal may include one of indium (In), lead (Pb), zinc (Zn), nickel (Ni), gold (Au), silver (Ag), copper (Cu), antimony (Sb), or bismuth (Bi).

Subsequently, the lower surface 130a of the upper connection pad 130 may be disposed on the upper surface 110a of the lower connection pad 110. For example, the upper solder 160 connected to the lower surface 130a of the upper connection pad 130 may be disposed on the lower solder 560 connected to the upper surface 110a of the lower connection pad 110. Subsequently, the upper solder 160 may be connected to the lower solder 560 by performing a thermal compression process thereon. For example, upper solder 160 is compressed downwardly towards the lower solder 560 during the thermal compression process.

Referring to FIGS. 11 to 13, while the thermal compression process is performed, the lower solder 560 may be chemically bonded to a portion of the lower connection pad 110, and the upper solder 160 may be chemically bonded to a portion of the upper connection pad 530. In some cases, for example, a portion of the upper solder 160 and a portion of the lower solder 560 may be chemically bonded. As a result, the intermetallic compound layer 540 may be formed between the upper surface 110a of the lower connection pad 110 and the lower surface 530a of the upper connection pad 530. For example, the intermetallic compound layer 540 may be formed as a layer by chemically bonding the portion of the lower connection pad 110, the lower solder 560, the upper solder 160, and the upper connection pad 530. After the thermal compression process is performed, the lower interlayer insulating layer 151 and the upper interlayer insulating layer 152 may become the interlayer insulating layer 150.

For example, the width W53 of the intermetallic compound layer 540 measured in the horizontal direction DR1 may be equal to the width W54 of the lower solder 560 measured in the horizontal direction DR1. For example, the thickness t51 of the intermetallic compound layer 540 measured in the vertical direction DR2 may be smaller than a sum of the thickness t52 of the lower solder 560 measured in the vertical direction DR2 and the thicknesses t2 of the upper solder 160 measured in the vertical direction DR2.

During the process of forming the intermetallic compound layer 540, the third metal is chemically bonded with each of the first metal and the second metal, such that a total volume of the upper solder 160 and the lower solder 560 is reduced. For example, in the process of forming the intermetallic compound layer 540, each of the portion of the lower connection pad 110 and the portion of the upper connection pad 530 is converted into the intermetallic compound layer 540, a total volume may be reduced due to the chemical bonding between the first, second, and third metals. Thus, the volume of the intermetallic compound layer 540 may be smaller than a sum of a volume of the lower solder 560 and a volume of the upper solder 160.

Although embodiments of the present disclosure have been described with reference to the accompanying drawings, embodiments of the present disclosure are not necessarily limited to the above embodiments, but may be implemented in various different forms. A person skilled in the art may appreciate that the present disclosure may be practiced in other concrete forms without departing from the technical spirit or essential characteristics of the present disclosure. Therefore, it should be appreciated that the embodiments as described above are not restrictive but illustrative in all respects.

What is claimed is:

1. A semiconductor package comprising:
a lower structure;
a lower conductive pad disposed on an upper surface of the lower structure;
a lower connection pad disposed on and connected to an upper surface of the lower conductive pad, wherein the lower connection pad includes a first metal;
an upper connection pad disposed on and spaced apart from an upper surface of the lower connection pad, wherein the upper connection pad includes a second metal;
an upper conductive pad disposed on and connected to an upper surface of the upper connection pad;
an upper structure disposed on an upper surface of the upper conductive pad; and
an intermetallic compound layer disposed between and in contact with at least a portion of the upper surface of the lower connection pad and a lower surface of the upper connection pad, wherein the intermetallic compound layer includes an intermetallic compound including the first metal, the second metal, and a third metal different from each of the first metal and the second metal,
wherein a width of the lower connection pad measured in a horizontal direction is greater than a width of the upper connection pad measured in the horizontal direction, and
wherein the horizontal direction is parallel to the upper surface of the lower structure.

2. The semiconductor package of claim 1, wherein a thickness of the intermetallic compound layer measured in a vertical direction is smaller than a thickness of the lower connection pad measured in the vertical direction and a thickness of the upper connection pad measured in the vertical direction.

3. The semiconductor package of claim 1, wherein a thickness of the intermetallic compound layer measured in a vertical direction ranges from 0.0005 μm to 0.01 μm.

4. The semiconductor package of claim 1, further comprising:
a lower passivation layer disposed on the upper surface of the lower structure, the upper surface of the lower conductive pad, and a sidewall of the lower conductive pad, wherein the lower passivation layer is in contact with at least a portion of a sidewall of the lower connection pad; and
an upper passivation layer disposed on a lower surface of the upper structure, a lower surface of the upper conductive pad, and a sidewall of the upper conductive pad, wherein the upper passivation layer is in contact with at least a portion of a sidewall of the upper connection pad.

5. The semiconductor package of claim 1, further comprising:
an interlayer insulating layer disposed between the upper surface of the lower structure and a lower surface of the upper structure, wherein the interlayer insulating layer is in contact with at least a portion of a sidewall of the lower connection pad, at least a portion of a sidewall of the upper connection pad, and at least a portion of a sidewall of the intermetallic compound layer.

6. The semiconductor package of claim 1, wherein the first metal and the second metal include a same metal.

7. The semiconductor package of claim 1, wherein the first metal and the second metal include different metals.

8. The semiconductor package of claim 1, wherein a width of the intermetallic compound layer measured in the horizontal direction is equal to the width of the upper connection pad measured in the horizontal direction.

9. The semiconductor package of claim 1, wherein a width of the intermetallic compound layer measured in the horizontal direction is equal to the width of the lower connection pad measured in the horizontal direction.

10. The semiconductor package of claim 1, wherein the intermetallic compound layer includes:
a first layer disposed on and in contact with the upper surface of the lower connection pad and the upper surface of the upper connection pad, wherein the first layer includes the intermetallic compound; and
a second layer surrounded by the first layer, wherein the second layer includes the third metal.

11. The semiconductor package of claim 1, wherein the intermetallic compound layer includes:
a first layer disposed on and in contact with the upper surface of the lower connection pad, wherein the first layer includes a first intermetallic compound including the first metal and the third metal; and
a second layer disposed on the first layer and in contact with the lower surface of the upper connection pad, wherein the second layer includes a second intermetallic compound including the second metal and the third metal.

12. A semiconductor package comprising:
a lower structure;
a lower connection pad disposed on an upper surface of the lower structure, wherein the lower connection pad includes a first metal;
an upper connection pad disposed on and spaced apart from an upper surface of the lower connection pad, wherein the upper connection pad includes the first metal;
an upper structure disposed on an upper surface of the upper connection pad;
an intermetallic compound layer disposed on and in contact with the upper surface of the lower connection pad and a lower surface of the upper connection pad, wherein the intermetallic compound layer includes an intermetallic compound including the first metal and a second metal different from the first metal;
an interlayer insulating layer disposed between the upper surface of the lower structure and a lower surface of the upper structure, wherein the interlayer insulating layer is in contact with a sidewall of the lower connection pad, a sidewall of the upper connection pad, and at least a portion of a sidewall of the intermetallic compound layer,
wherein a width of the lower connection pad measured in a horizontal direction is greater than a width of the upper connection pad measured in the horizontal direction.

13. The semiconductor package of claim 12, wherein the intermetallic compound layer uniformly includes the intermetallic compound.

14. The semiconductor package of claim 12, wherein at least a remaining portion of the sidewall of the intermetallic compound layer is in contact with the lower connection pad.

15. The semiconductor package of claim 12, wherein at least a portion of the intermetallic compound layer is in contact with a portion of the sidewall of the upper connection pad.

16. A method for manufacturing a semiconductor package, the method comprising:
forming a lower connection pad on an upper surface of a lower structure, wherein the lower connection pad includes a first metal;
forming an upper connection pad on a lower surface of an upper structure, wherein the upper connection pad includes the first metal;
forming a solder on a lower surface of the upper connection pad or an upper surface of the lower connection pad, wherein the solder includes a second metal different from the first metal;
positioning the lower surface of the upper connection pad on the upper surface of the lower connection pad; and
performing a thermal compression process such that a portion of the lower connection pad, the solder, and a portion of the upper connection pad are chemically bonded to form an intermetallic compound layer,
wherein the intermetallic compound layer includes an intermetallic compound including the first metal and the second metal, and
wherein a width of the lower connection pad measured in a horizontal direction is greater than a width of the upper connection pad measured in the horizontal direction.

17. The method of claim 16, wherein a volume of the intermetallic compound layer is smaller than a volume of the solder.

18. The method of claim 16, wherein the forming of the solder comprises:
forming the solder either on the lower surface of the upper connection pad or the upper surface of the lower connection pad.

19. The method of claim 16, wherein the forming of the solder comprises:
forming the solder on each of the lower surface of the upper connection pad and the upper surface of the lower connection pad.

20. The method of claim 16, wherein:
the intermetallic compound layer uniformly includes the intermetallic compound.
